(19) United States
(12) Patent Application Publication
(10) Pub. No.: US 2012/0012554 A1
(43) Pub. Date: Jan. 19, 2012

(54) SYSTEM AND METHOD OF FABRICATING MEDIA

(75) Inventors: Xiaoping Bian, Saratoga, CA (US); Qing Dai, San Jose, CA (US); Dan S. Kercher, Santa Cruz, CA (US); Mark F. Mercado, Morgan Hill, CA (US); Qi-fan Xiao, San Jose, CA (US); Jane J. Zhang, San Jose, CA (US)

(73) Assignee: Hitachi Global Storage Technologies Netherlands B.V., Amsterdam (NL)

(21) Appl. No.: 12/836,823

(22) Filed: Jul. 15, 2010

(51) Int. Cl. C23C 14/34

(52) U.S. Cl. 216/22; 204/298.02

(57) ABSTRACT

A method of fabricating media comprises forming recording media on a substrate. An overcoat is deposited on the recording media opposite the substrate. The overcoat has a first surface finish. The overcoat is etched to remove material and provide the overcoat with a second surface finish that is smoother than the first surface finish. The depositing and etching may occur sequentially in an in-situ, dry vacuum process. The second surface finish may not be mechanically processed after etching to further planarize the overcoat.

### BACKGROUND

1. Field of Disclosure

The present invention relates in general to hard disk drives and, in particular, to a system and method of fabricating media.

2. Description Of Related Art

The demand for higher areal density in hard disk drives requires a continuous reduction in the magnetic spacing of the interface between the head and the disk media. From the magnetic recording media perspective, a serious challenge to reducing magnetic spacing is the inherent limitations in the reduction of the thickness of the carbon overcoat on the disk media.

One limitation of conventional fabrication techniques is the surface roughness that they produce. A rough surface reduces the ability of a conventional overcoat to perform its function of providing intrinsic coverage, which leads to corrosion of the disk media. In addition, rough media provides less clearance for the head. Mechanical polishing processes such as final tape polish or burnish can smooth the surface. However, those processes also remove overcoat material that resides on the peaks of topography of the disk media, which again can lead to corrosion problems. Thus, improvements in surface smoothness design and an overcoat process that enhances coverage for disk media continue to be of interest.

### SUMMARY

Embodiments of a system and method of fabricating media are disclosed. In some embodiments, a method of fabricating a disk media comprises forming recording media on a substrate. An overcoat is deposited on the recording media opposite the substrate. The overcoat has a first surface finish.

The overcoat is etched to remove some of the overcoat material and provide a smoother surface. The second overcoat surface finish is smoother than the first surface finish. The etching may comprise ion beam etching. The second surface finish of the overcoat may not require mechanical processing after etching to further planarize the overcoat. The depositing and etching may occur sequentially in an in-situ, dry vacuum process.

In other embodiments, the depositing occurs in a vacuum comprising an inert gas and a reactive gas. After the etching step, the method may further comprise depositing the second overcoat on the second surface finish. The second overcoat substantially may have the second surface finish, and may not require further planarization by mechanical, etching or any other processes.

The foregoing and other objects and advantages of these embodiments will be apparent to those of ordinary skill in the art in view of the following detailed description, taken in conjunction with the appended claims and the accompanying drawings.

### BRIEF DESCRIPTION OF THE DRAWINGS

So that the manner in which the features and advantages of the embodiments are attained and can be understood in more detail, a more particular description may be had by reference to the embodiments thereof that are illustrated in the appended drawings. However, the drawings illustrate only some embodiments and therefore are not to be considered limiting in scope as there may be other equally effective embodiments.

FIGS. 1A and 1B are schematic isometric views of embodiments of a process for fabricating media;

FIGS. 2 and 3 are plots of two types of surface finish parameters, Rv(max) and Rq, for various embodiments of disk media, and depict the changes in surface roughness due to the etching process; and

FIG. 4 is a plot comparing the fly height control performance of conventional disk media to embodiments of disk media.

The use of the same reference symbols in different drawings indicates similar or identical items.

### DETAILED DESCRIPTION

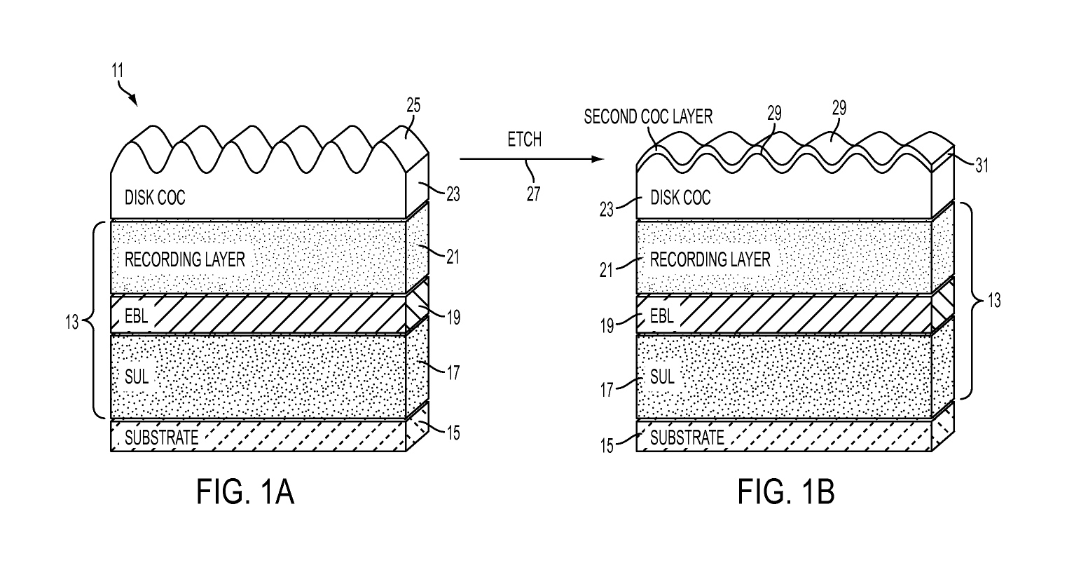

Embodiments of a system and method of fabricating media are disclosed. As shown in FIGS. 1A and 1B, one embodiment of a method of fabricating media 11, such as magnetic recording disk media, comprises forming recording media 13 on a substrate 15. For example, the recording media 13 may comprise perpendicular magnetic recording (PMR) media having a soft underlayer 17, an exchange break layer 19, and a recording layer 21. These layers may comprise a plurality of sub-layers depending on the application. The embodiments disclosed herein also are suitable for other types of media, as is known to those of ordinary skill in the art.

An overcoat 23 is deposited on the recording media 13 opposite the substrate 15. The depositing may occur in a vacuum comprising an inert gas, such as argon, etc. The overcoat may comprise a carbon overcoat (COC), such as amorphous or diamond-like carbon (DLC), Si-nitride, Si-carbide, etc. The overcoat has a first surface finish 25 (FIG. 1A) having peaks and valleys as shown.

The overcoat 23 is then etched 27 to remove at least some of the overcoat material. The etching 27 may comprise ion beam etching. Etching 27 provides the overcoat 23 with a second surface finish 29 (FIG. 1B) that is smoother than the first surface finish 25 (FIG. 1A). The second surface finish 29 of the overcoat 23 may not be further mechanically processed (e.g., final tape polished, etc.) after etching to further planarize the overcoat. The depositing and etching may occur sequentially in an in-situ, dry vacuum process.

In other embodiments, the etching occurs in a vacuum comprising an inert gas and at least one reactive gas, such as a dopant. For example, the reactive gas may comprise nitrogen, hydrogen, oxygen, xenon, krypton, neon or CO₂, or any combination thereof. After the etching step, the method may further comprise depositing a second overcoat 31 (FIG. 1B) on the second surface finish 29. The second overcoat 31 also may be a carbon overcoat. The second overcoat 31 substantially may have the second surface finish 29 as shown. In some embodiments, the second overcoat 31 may not require further planarization by mechanical, etching or any other processes.

Embodiments of the second surface finish are approximately 15% to 35% smoother than the first surface finish, and 20% to 30% smoother than the first surface finish in other versions. As will be further described herein, the second surface finish also comprises an average height (Ra) of approximately 0.20 to 0.35 Å, and 0.24 to 0.30 Å in other embodiments. The etching may comprise the removal of surface spikes or peaks for a duration of time of about 0.1 to 40 seconds, or 3 to 30 seconds in other embodiments. The etching may improve touchdown (TD) power on the disk by about 1 to 20 mW, or about 6 to 15 mW in other embodiments.

In some embodiments, a dry vacuum, in-situ process for planarizing the media surface of PMR media fabricates a low surface roughness. The media surface roughness is significantly reduced and the touchdown clearance is significantly improved compared to those produced by conventional techniques.

For example, a dry vacuum, ion-beam etch process is used to smooth a disk surface after a sputter deposition process. Again referring to FIG. 1A, a schematic representation of a near-finished PMR medium is shown. The first surface finish 25 shows high surface roughness due to the controlled atomic mobility and grain growth during the film sputtering process. However, by applying an in-situ, ion-beam etch 27 in one of the final steps of the vacuum process, the roughness of the second surface finish 29 can be significantly reduced as depicted in FIG. 1B. The planarized media with low surface roughness 29 may increase the head-disk interface clearance, which improves recording performance such as signal to noise ratio (SNR), overwrite (OW), resolution, etc. The low roughness also permits the use of a thinner carbon overcoat layer with enhanced media corrosion robustness.

Embodiments of the ion beam etch process may be used to polish the surface of a sputter-finished disk medium under a dry vacuum condition. For example, some of the etch process conditions that may be employed are summarized in Tables 1 and 2. These tables describe disk roughness properties under various surface treatment conditions. In this disclosure, the following definitions are provided for the surface finish terms Ra, Rq, Rp and Rv.

Ra: mathematical average of all positive and negative heights;

Rq: root mean square (rms);

Rp: peak to mean;

Rv: valley to mean; and

Rv-max: the maximum valley to mean.

TABLE 1
Comparison of samples

| Sample | Rv-max (Å) | Rq (Å) |
|---|---|---|
| DLC Control (unetched) | 2.40 | 0.56 |
| 3s etch | 2.08 | 0.50 |
| 6s etch | 1.84 | 0.47 |
| 9s etch | 1.78 | 0.43 |
| 9s etch + CNₓ carbon | 1.89 | 0.43 |

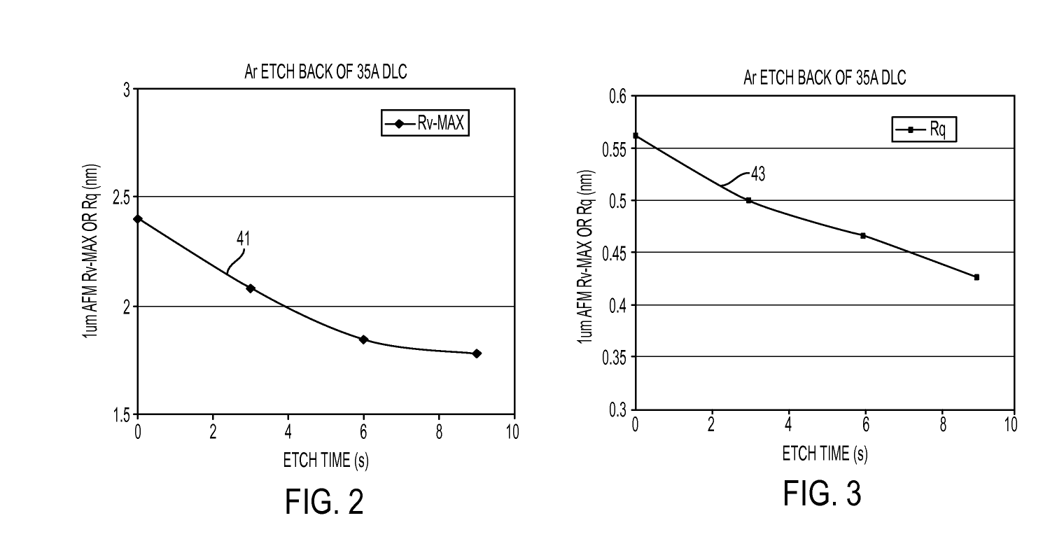

Comparison of surface roughness for samples of media with surface etching and without surface etching reveals significant surface topographic change after the etch process. This data indicates the removal of at least some surface spike peaks. FIGS. 2 and 3 depict plots 41, 43, respectively, of the roughness parameters Rv-max, Rq as functions of the etch process time. Table 2 provides additional data comparing etched and unetched samples of media.

TABLE 2
More examples of finished media

| Sample | Process | Ra (Å) | Rq (Å) | Rp (Å) | Rv (Å) |
|---|---|---|---|---|---|
| Reference | unetched | 0.38 | 0.48 | 1.85 | 2.11 |
| Ex. 1 | 3s etch | 0.30 | 0.38 | 1.55 | 1.61 |
| Ex. 2 | 6s etch | 0.26 | 0.33 | 1.33 | 1.48 |
| Ex. 3 | 9s etch | 0.24 | 0.30 | 1.27 | 1.34 |
| Ex. 4 | 10s etch + | 0.26 | 0.33 | 1.33 | 1.73 |
| | N₂ | | | | |

At selected etch conditions, the Rv-max is reduced by about 26% compared to unetched media. Furthermore, for some embodiments of surface-etched media, the redeposition of an additional carbon overcoat layer (CNₓ) still preserves the surface smoothness. This feature provides a significant benefit to the selection of lubrication at the hard disk drive integration level.

Table 3 summarizes the effect of varying etch process parameters on the magnetic properties for media.

TABLE 3
No significant changes in the magnetic properties of the samples

| | | A side | | | | B side | | | |
|---|---|---|---|---|---|---|---|---|---|
| | | of disk | | | | of disk | | | |
| Sample | | Hc1 | H_n | SFD | Hs | Hc1 | H_n | SFD | Hs |
| | Ar etch | | | | | | | | |
| Ex. 1 | 3 s | 5145 | −2315 | 3010 | 8432 | 5147 | −2267 | 2981 | 8448 |
| Ex. 2 | 6 s | 5136 | −2312 | 3004 | 8421 | 5156 | −2304 | 2975 | 8473 |
| Ex. 3 | 9 s | 5139 | −2299 | 3001 | 8430 | 5110 | −2305 | 3085 | 8467 |
| Reference 1 | None | 5142 | −2310 | 2995 | 8446 | 5136 | 2255 | 3030 | 8486 |
| | N₂ etch | | | | | | | | |
| Reference 2 | None | 5139 | −2331 | 2968 | 8437 | 5146 | −2281 | 3014 | 8501 |
| Ex. 4 | 10 s | 5140 | −2310 | 2982 | 8405 | 5147 | −2286 | 2992 | 8462 |
| Ex. 5 | 20 s | 5107 | −2261 | 2981 | 8389 | 5116 | −2244 | 3003 | 8454 |
| Ex. 6 | 30 s | 5147 | −2311 | 2993 | 8433 | 5145 | −2275 | 3024 | 8479 |

This data clearly shows that the magnetic properties performance of media is substantially insensitive to the overcoat etching process under both argon and nitrogen-doped conditions. This indicates that the surface etching process is readily implemented in current media production.

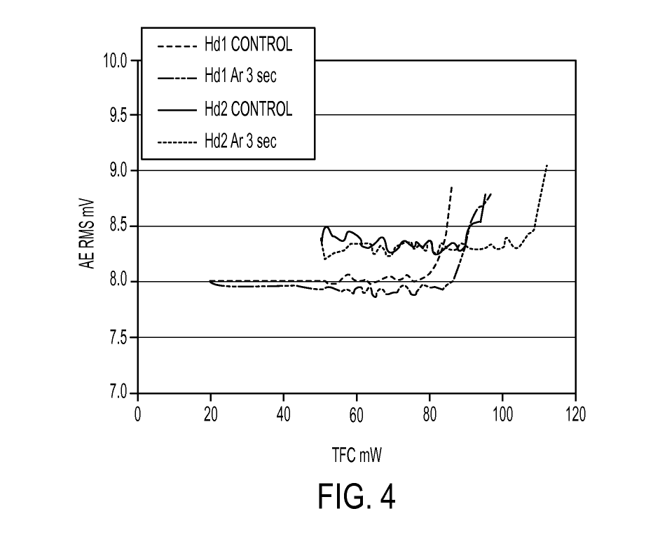

FIG. 4 depicts plots from a spin stand, thermal fly-height control (TFC) test. This test compares control or unetched media with etched media, for two different disk drive heads. The measured AE signal indicates a TFC touchdown (TD) power increase in the range of 6 mW to 15 mW for the surface etched media compared to the unetched media. This provides a significant increase in head-media clearance due to the planarization process described herein.

Table 4 summarizes data from a Guzik spin stand test comparing etched and unetched media. The media with etched carbon overcoats show better OW, SNR, low frequency (LF) amplitude and bit error rate (BER), which are consistent with the gain in touchdown (TD) power.

TABLE 4
More performance comparisons

| | | | | | | | | | | TD |
|---|---|---|---|---|---|---|---|---|---|---|
| Sample | OW | 2TSNR | 2TSNoNR | 10TMCW | BER | T50 | LFmV | RES | ACSQZ % | (mW) |
| Etched | 34.0 | 19.9 | 27.5 | 79.3 | −5.1 | 20.9 | 19.3 | 41.4 | 41.9 | 77.3 |
| Unetched | 32.8 | 19.3 | 26.9 | 78.7 | −4.4 | 21.0 | 17.4 | 41.6 | 48.5 | 71.1 |

Under the TFC touchdown and constant pull back condition, the etched media show a clear advantage in recording performance. For the surface-etched disk, OW of the media improved by about 0.5 to 3 dB, or about 1.2 dB in some embodiments. SNR of the media improved by about 0.1 to 2 dB, or about 0.5 and 1 dB in some embodiments. Etching also improves LF of the media by about 1% to 20%, or about 11% in some embodiments. Etching further improved the BER of the media by about 10% to 20%, or about 16% in some embodiments. Accordingly, the overall corrosion resistance of media with an etched COC is about 2 to 10 times better than that of conventional media having unetched COC.

As shown in Table 5, etching the carbon overcoat also provides much better corrosion resistance, such as lower cobalt extraction, compared to unetched overcoats.

TABLE 5
Cobalt extraction experiment

| Sample | Process | COC thickness (Å) | Co extraction |
|---|---|---|---|
| Ex. 1 | 3s etch | 31.5 | 5.3 |
| Ex. 2 | 6s etch | 30.0 | 0.2 |
| Ex. 3 | 9s etch | 29.9 | 1.7 |
| Ex. 4 | Unetched | 35.0 | 12.0 |

Low cobalt counts were observed for the etched disks, even with thinner layers of COC, which indicates better corrosion resistance. These performance benefits provide a path for further extension of current PMR technology in the hard disk drive industry.

These processes may be performed on different types of equipment. Traditionally, carbon overcoats are deposited by a sputtering process, but producing 30 Å robust carbon overcoats using sputtering is not feasible. Presently, technologies such as ion beam deposition, plasma-enhanced chemical vapor deposition, and filtered cathodic arc systems can produce thin protective carbon overcoats. In particular, ion beam carbon (IBC) deposition technology produces superior thin, durable, and manufacturable robust carbon overcoats. In the IBC process, a hydrocarbon (CₓH_{y}) gas is used as a precursor, and a plasma is generated by ionizing the hydrocarbon molecules. These ionized species are directed towards the target. High impact energy ions provide a higher fraction of diamond-like content in the carbon overcoat that leads to high hardness, high density, and high elastic modulus. In addition, ion beam carbon overcoats have significantly higher resistance to tribochemical wear and corrosion. Adversely, the ion beam process can be used to etch material from a target object such as a carbon coated disk medium.

Again referring to FIGS. 1A and 1B, embodiments of a system of fabricating workpieces comprises a sputtering system having a plurality of process stations for fabricating workpieces. At least one of the process stations is an overcoat process station that deposits an overcoat on a workpiece to provide the workpiece with a first surface finish, and sequentially etches the overcoat to provide the overcoat with a second surface finish that is smoother than the first surface finish. The second surface finish of the overcoat may not be mechanically processed to further planarize the overcoat after etching. The at least one of the process stations may comprise a first overcoat process station for depositing the overcoat, and a second overcoat process station for ion beam etching the overcoat.

The workpieces may comprise magnetic media, solid state memory, semiconductors, magnetic random access memory, or solar thin films. The at least one of the process stations may comprise an in-situ, dry vacuum process. In addition, the at least one of the process stations may deposit a second overcoat on the second surface finish substantially having the second surface finish.

This written description uses examples to disclose the embodiments, including the best mode, and also to enable those of ordinary skill in the art to make and use the invention. The patentable scope is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

As used herein, the terms “comprises,” “comprising,” “includes,” “including,” “has,” “having” or any other variation thereof, are intended to cover a non-exclusive inclusion. For example, a process, method, article, or apparatus that comprises a list of features is not necessarily limited only to those features but may include other features not expressly listed or inherent to such process, method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” are employed to describe elements and components described herein. This is done merely for convenience and to give a general sense of the scope of the invention. This description should be read to include one or at least one and the singular also includes the plural unless it is obvious that it is meant otherwise.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

After reading the specification, skilled artisans will appreciate that certain features are, for clarity, described herein in the context of separate embodiments, may also be provided in combination in a single embodiment. Conversely, various features that are, for brevity, described in the context of a single embodiment, may also be provided separately or in any subcombination. Further, references to values stated in ranges include each and every value within that range.

What is claimed is:

1. A method of fabricating media, comprising:
forming recording media on a substrate;
depositing an overcoat on the recording media opposite the substrate, the overcoat having a first surface finish; and then
etching the overcoat to remove material and provide the overcoat with a second surface finish that is smoother than the first surface finish.

2. A method according to claim 1, wherein the second surface finish of the overcoat is not mechanically processed to further planarize the overcoat after etching.

3. A method according to claim 1, wherein the depositing occurs in a vacuum comprising an inert gas, etching comprises ion beam etching, and the second surface finish is approximately 15% to 35% smoother than the first surface finish.

4. A method according to claim 1, wherein the depositing occurs in a vacuum comprising an inert gas and a reactive gas comprising at least one of nitrogen, hydrogen, oxygen, xenon, krypton, neon and CO₂, and the second surface finish is approximately 20% to 30% smoother than the first surface finish.

5. A method according to claim 1, wherein the depositing and etching occur sequentially in an in-situ, dry vacuum process, the recording media is perpendicular magnetic recording media, and the overcoat is a carbon overcoat.

6. A method according to claim 1, wherein after etching, further comprising depositing a second overcoat on the second surface finish, and the second overcoat is a second carbon overcoat substantially having the second surface finish.

7. A method according to claim 6, wherein the second overcoat is not mechanically processed to further planarize the second overcoat.

8. A method according to claim 1, wherein the second surface finish has an average height (Ra) of approximately 0.20 to 0.35 Å, and etching comprises removal of spike peaks over a duration of time of about 0.1 to 40 seconds.

9. A method according to claim 1, wherein the second surface finish has an average height (Ra) of approximately 0.24 to 0.30 Å, and etching comprises removal of spike peaks over a duration of about 3 to 30 seconds.

10. A method according to claim 1, wherein etching improves (a) recording head touchdown (TD) power by about 1 to 20 mW, and (b) overwrite (OW) of the unetched media by about 0.5 to 3 dB, compared to media with an unetched carbon overcoat.

11. A method according to claim 1, wherein etching improves (a) recording head touchdown (TD) power by about 6 to 15 mW, and (b) signal-to-noise ratio (SNR) by about 0.1 to 2 dB, compared to media with an unetched carbon overcoat.

12. A method according to claim 1, wherein etching improves (a) signal-to-noise ratio (SNR) by about 0.5 to 1.0 dB, (b) low frequency amplitude by about 1% to 20%, and (c) bit error rate (BER) by about 10% to 20%, compared to media with an unetched carbon overcoat.

13. A system of fabricating workpieces, comprising:
a sputtering system having a plurality of process stations for fabricating workpieces; and
at least one of the process stations is an overcoat process station that deposits an overcoat on a workpiece to provide the workpiece with a first surface finish, and sequentially etches the overcoat to provide the overcoat with a second surface finish that is smoother than the first surface finish.

14. A system according to claim 13, wherein the at least one of the process stations comprises a first overcoat process station for depositing the overcoat, and a second overcoat process station for ion beam etching the overcoat.

15. A system according to claim 13, wherein the workpieces comprise magnetic media, solid state memory, semiconductors, magnetic random access memory, or solar thin films, and the second surface finish of the overcoat is not mechanically processed to further planarize the overcoat after etching.

16. A system according to claim 13, wherein the at least one of the process stations comprises an in-situ, dry vacuum process that uses an inert gas and a reactive gas comprising at least one of nitrogen, hydrogen, oxygen, xenon, krypton, neon and CO₂, and the overcoat is a carbon overcoat.

17. A system according to claim 13, wherein the at least one of the process stations deposits a second overcoat on the second surface finish, and the second overcoat is a second carbon overcoat substantially having the second surface finish.

18. A system according to claim 13, wherein the second surface finish is approximately 15% to 35% smoother than the first surface finish, the second surface finish has an average height (Ra) of approximately 0.20 to 0.35 Å, and etching comprises removal of spike peaks over a duration of time of about 0.1 to 40 seconds.

19. A system according to claim 13, wherein etching improves (a) recording head touchdown (TD) power by about 1 to 20 mW, and (b) overwrite (OW) of the unetched media by about 0.5 to 3 dB, compared to media with an unetched carbon overcoat.

20. A system according to claim 13, wherein etching improves (a) signal-to-noise ratio (SNR) by about 0.5 to 1.0 dB, (b) low frequency amplitude by about 1% to 20%, and (c) bit error rate (BER) by about 10% to 20%, compared to media with an unetched carbon overcoat.
